(19) United States
(12) Patent Application Publication
(10) Pub. No.: US 2008/0087979 A1
(43) Pub. Date: Apr. 17, 2008

(54) Integrated Circuit with Back Side Conductive Paths

(75) Inventors: Thomas M. Goida, Windham, NH (US); Richard J. Sullivan, Salem, MA (US); Michael J. Zylinski, Haverhill, MA (US)

Correspondence Address: BROMBERG & SUNSTEIN LLP, 125 SUMMER STREET, BOSTON, MA, 02110-1618, US

(73) Assignee: ANALOG DEVICES, INC., Norwood, MA (US)

(21) Appl. No.: 11/549,342

(22) Filed: Oct. 13, 2006

(51) Int. Cl. H01L 29/00

(52) U.S. Cl. 257/502

(57) ABSTRACT

An integrated circuit has a substrate with a back side and a front side. The front side has both a working area and a front side contact in electrical communication with the working area. In a similar manner, the back side has first and second back side contacts. A first conductive path extending through the substrate electrically connects the front side contact and the first back side contact. In addition, a second conductive path electrically connects the first back side contact with the second back side contact.

### FIELD OF THE INVENTION

The invention generally relates to integrated circuits and, more particularly, the invention relates to routing electrical signals within and on an integrated circuit.

### BACKGROUND OF THE INVENTION

To perform their underlying functions, many electronic devices have circuit components, such as integrated circuit chips or discrete circuitry, mounted to internal circuit boards. For example, to provide its basic functionality, a personal computer generally has several circuit boards that cooperate to process data. One such circuit board, known as a “motherboard,” interconnects a microprocessor chip to other electronic components within the computer system.

In an effort to increase consumer demand and revenue, the electronics industry continually strives to improve existing electronic devices. Such improvements commonly are implemented by crowding increasing numbers of electronic components onto already crowded circuit boards. For example, one current trend adds video capability to cell phones. When adding this capability to their existing technologies, cell phone designers simply may add a video chip to an existing generation circuit board having a different function (e.g., power regulation).

Accordingly, the corresponding circuit board in the next generation cell phone may have circuitry that performs its prior generation function (e.g., power regulation), as well as an additional video chip for providing the video capability. The circuit board must be large enough, however, to support an additional video chip. One way to meet this demand is simply to increase the size of the circuit board, which, undesirably, is antithetical to current trends of reducing the size of electronic devices.

### SUMMARY OF THE INVENTION

In accordance with one embodiment of the invention, an integrated circuit has a substrate with a back side and a front side. The front side has both a working area and a front side contact in electrical communication with the working area. In a similar manner, the back side has first and second back side contacts. A first conductive path extending through the substrate electrically connects the front side contact and the first back side contact. In addition, a second conductive path electrically connects the first back side contact with the second back side contact.

Some embodiments have a surface insulator that passivates the second conductive path on the back side of the substrate. In addition, the working area may have one or more functional components. For example, the working area may have MEMS structure, circuitry, or both.

Fabrication processes illustratively form the first conductive path so that it is substantially integrated with the substrate. Moreover, such processes also may form the first conductive path to be not straight. In addition, or in the alternative, the second conductive path also may be substantially integrated with the substrate. For example, the second conductive path may be positioned between the front side and the back side of the substrate, or on the back side surface (e.g., with or without passivation). In some embodiments, the back side of the substrate has a third back side contact. In that case, the second conductive path may electrically connect the third back side contact with the first back side contact.

In accordance with another embodiment of the invention, an electronic apparatus has a substrate with a front side with a front side contact, and a back side with first and second back side contacts. A first conductive path extending through the substrate electrically connects the front side contact and the first back side contact. In a corresponding manner, a second conductive path on the back side of the substrate electrically connects the first back side contact with the second back side contact.

The apparatus may have additional components. For example, the apparatus also may have an integrated circuit mechanically connected with at least one of the first back side contact or the second back side contact. In addition, or in the alternative, the apparatus also may have a circuit board with a top surface that is mechanically connected with the front side contact. The top surface of the circuit board also is connected with at least one additional circuit element on such circuit board.

A number of different conductors may be used for either of the conductive paths. For example, the first conductive path may comprise a via lined or filled with a conductive polysilicon.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows system that may use an integrated circuit configured in accordance with illustrative embodiments of the invention.

FIG. 2A schematically shows a perspective bottom view of an integrated circuit configured in accordance with illustrative embodiments of the invention.

FIG. 2B schematically shows a perspective top view of an integrated circuit configured in accordance with illustrative embodiments of the invention.

FIG. 3 schematically shows a cross-sectional view of two integrated circuits in a stacked configuration, where one of the integrated circuits is configured in a manner similar to the integrated circuit of FIGS. 2A and 2B.

FIG. 4 shows a process of producing an integrated circuit in accordance with illustrative embodiments of the invention.

### DESCRIPTION OF ILLUSTRATIVE EMBODIMENTS

In illustrative embodiments of the invention, an integrated circuit has a conductive path that effectively extends from its front side, through its substrate and across its back side. Such a topology more efficiently enables multiple chips to be mounted in a stacked configuration, consequently reducing space requirements of an underlying circuit board or similar circuit mounting apparatus. Details illustrative embodiments are discussed below.

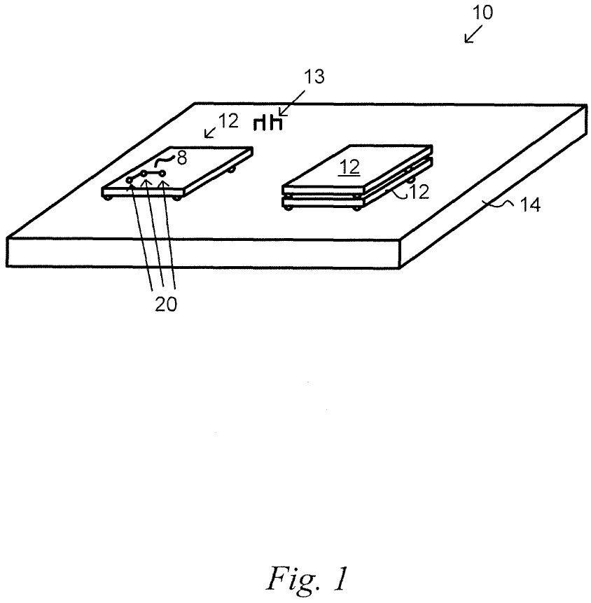

FIG. 1 schematically shows a perspective view of a system 10 using an integrated circuit 12 configured in accordance with illustrative embodiments of the invention. The system 10 may be any conventional electronic system that commonly uses integrated circuits 12. For example, the system 10 may be part of an air bag deployment system within an automobile, part of a microphone system within a cellular telephone, or part of a motherboard in a computer system.

To that end, the system 10 has a circuit board 14 supporting and selectively interconnecting a plurality of different electronic components. Among other things, the components can include analog circuits, digital circuits, integrated circuits, and discrete components. As shown, the circuit board 14 has three integrated circuits 12 and another circuit element 13 (e.g., a capacitor). Two of the integrated circuits 12 are configured in accordance with illustrative embodiments of invention.

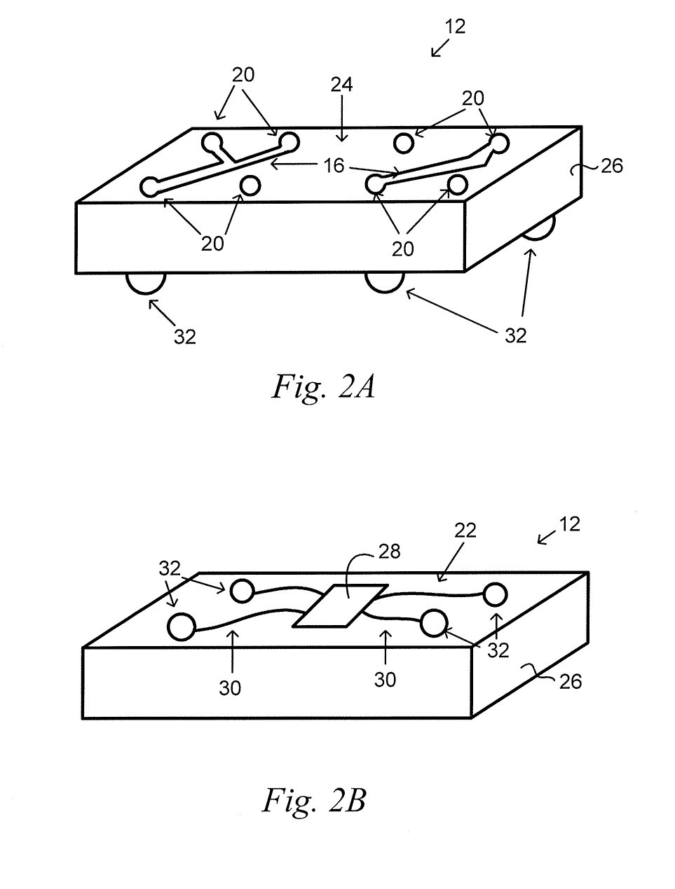

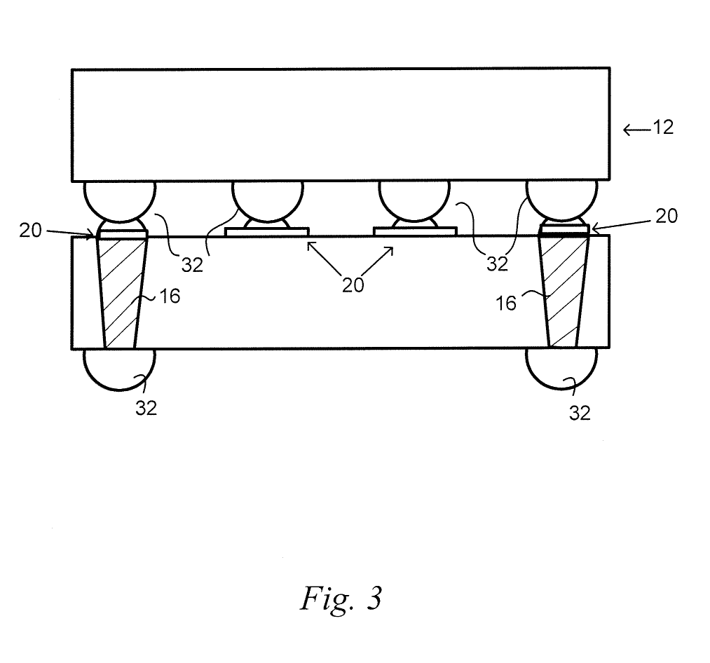

Specifically, as discussed below, the two integrated circuits 12 configured in accordance with illustrative embodiments each have a conductive path 16 extending between the front and back sides 22 and 24 of their respective substrates 26 (see FIG. 3, discussed below). Conductive traces 18 leading to one or more contact pads 20 on their back sides 24 facilitate a direct connection with another integrated circuit 12 in a stacked configuration (discussed below in greater detail with regard to FIGS. 2A, 2B and 3). To illustrate this, one of the two integrated circuits 12 in FIG. 1 supports another integrated circuit 12 on its back side 24. The supported integrated circuit 12 may be configured in accordance with illustrative embodiments, or may be a conventional integrated circuit, which does not have the noted conductive path 16 and traces 18. These two coupled integrated circuits 12 are referred to herein as being in a “stacked configuration.”

The integrated circuits 12 shown in FIG. 1 illustratively are flip-chip devices configured to perform a specific function. Among other things, one or both of the integrated circuits 12 may have circuitry only, a MEMS device, or both circuitry and a MEMS device. As an example, if it has a MEMS device, the integrated circuit 12 may implement the functionality of, among other things, an accelerometer for detecting linear acceleration, or a gyroscope for detecting angular rotation. Exemplary MEMS accelerometers are discussed in greater detail in U.S. Pat. No. 5,939,633, which is assigned to Analog Devices, Inc. of Norwood, Mass. Exemplary MEMS gyroscopes are discussed in greater detail in U.S. Pat. No. 6,505,511, which also is assigned to Analog Devices, Inc. of Norwood, Mass. The disclosures of U.S. Pat. Nos. 5,939,633 and 6,505,511 are incorporated herein, in their entireties, by reference.

The integrated circuits 12 may implement other types of MEMS devices or other circuit functionality. For example, the integrated circuits 12 may implement a MEMS microphone or pressure sensor. As yet another example, the integrated circuits 12 may implement conventional circuit functionality, such as an operational amplifier, an analog-to-digital converter, and/or a microprocessor.

In a similar manner, a conventional package may contain and protect the MEMS device, which itself may be in a flip-chip or non-flip chip configuration. Accordingly, discussion of the type of device on the integrated circuit 12 and specific packaging is illustrative and not intended to limit various embodiments of the invention.

FIGS. 2A and 2B schematically show perspective views of an integrated circuit 12 configured in accordance with illustrative embodiments of the invention. Specifically, FIG. 2A shows the back side 24 of the integrated circuit 12, while FIG. 2B shows the front side 22 of the integrated circuit 12.

As shown in FIG. 2A, the integrated circuit 12 has a substrate 26 with a back side 24 having a plurality of contact pads 20 for connecting with other integrated circuits or circuit devices. For example, the contact pads 20 may be used to connect with solder balls of a second integrated circuit 12 in a stacked configuration as shown in FIG. 1. Alternatively, the contact pads 20 may connect to other components or devices by conventional means, such as through wire bonds.

Conductive traces 18 on the back side 24 electrically connect together selected contact pads 20. For example, the integrated circuit 12 shown in FIG. 2 has a first conductive trace 18 connecting together three contact pads 20, and a second conductive trace 18 connecting together two other contact pads 20. The back side 24 also has three additional contact pads 20 that are not connected to other contact pads 20.

Of course, those skilled in the art can form conductive traces 18 or other similar interconnecting conductors on the back side 24 of the substrate 26 in any configuration as required by the intended application. To that end, a circuit designer may electrically connect certain contact pads 20 based upon the corresponding land configuration of the integrated circuit 12 that is to be mounted on its back side 24. Alternatively, a circuit designer may electrically connect certain contact pads 20 to provide flexibility for integrated circuits 12 having a variety of different corresponding land configurations. For example, a circuit designer may connect specific pads 20 so that it readily connects with integrated circuits 12 having two different land patterns. Accordingly, the configuration shown in FIG. 2A is illustrative and not intended to limit various embodiments of the invention.

FIG. 2B shows the front side 22, which is directly opposite the back side 24. This front side 22 illustratively has a working portion 28 implementing some functionality. As noted above, this functionality may be electronic, MEMS, or both. To transmit electrical signals between the front and back sides 22 and 24, the integrated circuit 12 has one or more conductive paths 16 extending through the substrate 26 (see FIG. 3 for a cross-sectional view of the conductive paths 16).

Interconnects 30 on the front side 22 electrically connect the working portion 28 with one or more of the conductive paths 16. These conductive paths 16 may terminate at a first type of contact pad 20. Specifically, the first type of contact pad 20 is directly connected to the conductive path terminus point on the back side 24 (i.e., effectively forming part of the conductive path 16). Moreover, conductive traces 18 on the back side 24 may connect the conductive paths 16 with contact pads 20 that are not directly connected with the conductive paths 16. This second type of contact pad 20 may be formed by depositing metal on a back side surface that is not the terminus of a conductive path 16. For example, as discussed below, this type of contact pad 20 may have been formed on an insulator that is deposited on the back side surface. Such pad 20 has no direct connection to the conductive path 16 through the substrate 26. Accordingly, the working portion 28 can forward and/or receive an electronic signal via a complete transmission line comprising the following links:
interconnect 30,
conductive path 16
first type of contact pad 20,
conductive trace 18, and
second type of contact pad 20.

The front side 22 of the of the substrate 26 also has a plurality of mechanical contacts 32 for electrical and mechanically connecting with another apparatus. Among other things, the mechanical contacts 32 may be one or more conventional solder balls (also referred to as “solder balls 32”). Each solder ball 32 directly connects to the conductive path 16 through the substrate 26. Alternatively, one or more of the solder balls 32 may not directly contact one of the conductive paths 16 through the substrate 26.

FIG. 3 schematically shows a cross-sectional view of the top and bottom integrated circuits 12 connected in the stacked configuration shown in FIG. 1. In this example, the top integrated circuit 12 is a conventional integrated circuit having a plurality of solder balls 32 that connect with contact pads 20 on the bottom integrated circuit 12. Conventional means (e.g., solder paste) may be used to connect the solder balls 32 to the contact pads 20 of the bottom integrated circuit 12.

The bottom integrated circuit 12 is configured in accordance with illustrative embodiments of the invention. The conductive paths 16 through the bottom integrated circuit 12 are shown as extending straight through the substrate 26 with a substantially uniformly changing diameter. However, some embodiments of the conductive path 16 have a substantially uniform diameter, irregular shape, irregular outer dimension, and/or do not extend straight through the substrate 26. For example, the conductive paths 16 may extend somewhat diagonally through the substrate 26. Discussion of one type of conductive path 16 therefore is illustrative and not intended to limit the number of embodiments of the invention.

In some embodiments, the top integrated circuit 12 in FIG. 3 may be configured in a manner similar to that of the bottom integrated circuit 12; namely, it has a conductive path 16 through the substrate 26 that connects with conductive traces 18 on the back side 24. In fact, some embodiments connect more than two integrated circuits 12 in a stacked configuration (e.g., three or four integrated circuits 12 stacked on one another). Accordingly, discussion of just two integrated circuits 12 in a stacked configuration is for convenience only.

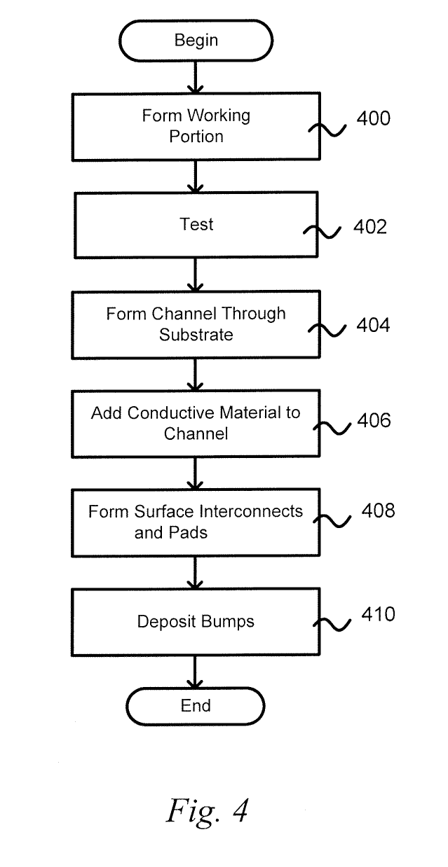

FIG. 4 shows a process of forming an integrated circuit 12 in accordance with illustrative embodiments of invention. Those skilled in the art should understand that multiple circuit die may be formed simultaneously in a batch process on a single wafer. For simplicity, however, this process is discussed as forming a single die on a single wafer.

The process begins at step 400 by forming a working portion 28 on a wafer, e.g., a single crystal silicon wafer, in a conventional manner. As noted above, the working portion 28 can have circuitry, MEMS structure, or both. If necessary, the working portion 28 may be capped, or otherwise protected at this or some later point in the process (e.g., see step 408, which discusses passivation).

The process continues to step 402, where the working portion 28 is tested to ensure that it works satisfactorily for its intended purpose. At this point, a fully functional device may be considered to be formed. This device, however, also requires some additional interconnect apparatus to connect with other devices, such as other integrated circuits 12 through the circuit board 14 as shown in FIG. 1.

Accordingly, the process forms one or more conductive paths 16 to communicate with other devices. To that end, step 404 of the process forms a channel from the substrate front side 22 (i.e., the side having the working portion 28) to the substrate back side 24. This channel may be referred to in the art as a “via.”

After forming the channel through the substrate 26, the process continues to step 406, which adds conductive material to the channel to form the conductive path 16 through the substrate 26. In some embodiments, the conductive material may fill the entire channel. In other embodiments, the conductive material coats at least a portion of the wall(s) of the channel. In either case, the conductive path 16 is considered to be integrated with the substrate 26. Among other things, the conductive material may be a metal or doped polysilicon. For interconnection purposes, the terminus portion of each conductive path 16 may be considered to effectively form a “front side contact.” Alternatively, an additional step may add a front side contact of like or different material. The process thus may form the interconnects 30 between the front side contacts and working portion 28 at this time.

Rather than directly adding the conductive material to the channel, some embodiments add an insulator to the channel walls to electrically isolate the conductive path 16 from the substrate 26. As an example, the insulator may be an oxide that is grown or deposited in accordance with conventional processes. After applying the insulator 16 to the wall(s), the conductive material is added.

The process continues to step 408, which forms the back side electrical connections. Specifically, the process deposits connector material to form the contact pads 20 and conductive traces 18. In a manner similar to the conductive paths 16 through the substrate 26, the contact pads 20 and conductive traces 18 are considered to be integrated with the substrate 26. These electrical connections may be formed by first applying an insulator to a portion of the back side 24, and then forming the conductive traces 18 on the insulator. Among other ways, illustrative embodiments may apply the conductive material to the insulator layer by means of a conventional sputtered metal process, or an electroplating process. Another layer of insulator also may be deposited on the back side 24, front side 22, or both, to collectively insulate the exposed portions of the conductive traces 18 and interconnects 30. This insulation process, which often is referred to in the art as “passivation,” may use any number of materials, such as a nitride or polyimide.

Accordingly, the conductive traces 18 may be considered to be on the back side 24 of the substrate 26 even if covered by some other material. As another example, some embodiments may etch trenches in the surface of the back side 24, insulate the trenches with an oxide, and then deposit a doped polysilicon or metal into the insulated trenches. Additional passivation may then cover the conductive traces 18, or other layers may be formed over the trenches.

The process concludes at step 410 by depositing the solder balls 32 on the front side 22 of the substrate 26. The solder balls 32 may be any conventional solder material, such as a conventional SAC solder, which includes tin, silver, and copper. Solder balls 32 directly connected to the conductive paths 16 may be considered to be part of the front side contacts.

At this point, the integrated circuit 12 may be packaged within a conventional package, or secured directly to a printed circuit board 14, as shown in FIG. 1. Of course, those skilled in the art should understand that one or more of the discussed integrated circuits 12 may be connected in a stacked configuration whether or not they are packaged. For example, a tall package may contain four integrated circuits 12 in a stacked configuration, i.e., four integrated circuits 12 connected on top of one another.

It should be noted that the process of FIG. 4 provides some basic steps of one process for forming an integrated circuit 12 in accordance of illustrative embodiments of the invention. For example, additional testing steps are not discussed. Those skilled in the art nevertheless should understand that additional steps may be taken to form a viable integrated circuit 12.

Moreover, some of the steps in the process may be executed in an order that is different than that discussed above. For example, the working portion 28 may be formed after forming the conductive path 16 through the substrate 26. Accordingly, discussion of the process of FIG. 4 is illustrative and not intended to limit a number of other embodiments of the invention.

By extending the conductive path 16 through the substrate 26, the conductive traces 18 on the back side 24 efficiently distribute electrical signals to and from the working portion 28 to multiple contact pads 20. Accordingly, illustrative embodiments efficiently enable integrated circuits 12 to be connected in a stacked configuration.

Although the above discussion discloses various exemplary embodiments of the invention, it should be apparent that those skilled in the art can make various modifications that will achieve some of the advantages of the invention without departing from the true scope of the invention.

What is claimed is:

1. An integrated circuit comprising:
a substrate having a front side and a back side;
a working area on the front side;
a front side contact on the front side of the substrate, the front side contact being in electrical communication with the working area;
a first back side contact and a second back side contact, the first and second back side contacts being on the back side of the substrate;
a first conductive path extending through the substrate, the first conductive path electrically connecting the front side contact and the first back side contact; and
a second conductive path electrically connecting the first back side contact with the second back side contact.

2. The integrated circuit as defined by claim 1 further comprising a surface insulator that passivates the second conductive path on the back side of the substrate.

3. The integrated circuit as defined by claim 1 wherein the working area comprises circuitry or MEMS structure.

4. The integrated circuit as defined by claim 1 wherein the first conductive path is substantially integrated with the substrate.

5. The integrated circuit as defined by claim 1 wherein the second conductive path is substantially integrated with the substrate.

6. The integrated circuit as defined by claim 1 wherein the back side of the substrate has a third back side contact, the second conductive path electrically connecting the third back side contact with the first back side contact.

7. The integrated circuit as defined by claim 1 wherein the first conductive path is not straight.

8. The integrated circuit as defined by claim 1 wherein the first conductive path is between the front side and the back side of the substrate.

9. An electronic apparatus comprising:
a substrate having a front side and a back side;
a front side contact on the front side of the substrate;
a first back side contact and a second back side contact, the first and second back side contacts being on the back side of the substrate;
a first conductive path extending through the substrate, the first conductive path electrically connecting the front side contact and the first back side contact; and
a second conductive path on the back side of the substrate, the second conductive path electrically connecting the first back side contact with the second back side contact.

10. The apparatus as defined by claim 9 further comprising an integrated circuit mechanically connected with at least one of the first back side contact or the second back side contact.

11. The apparatus as defined by claim 10 further comprising a circuit board having a top surface that is mechanically connected with the front side contact, the top surface of the circuit board also being connected with at least one additional circuit element.

12. The apparatus as defined by claim 9 further comprising a working portion on the front side of the substrate, the working portion being in electrical communication with the front side contact.

13. The apparatus as defined by claim 12 wherein the working portion comprises at least one of circuitry and MEMS structure.

14. The apparatus as defined by claim 9 wherein further comprising an insulator for passivating the second conducive path.

15. The apparatus as defined by claim 9 wherein the first conductive path comprises a via and electrically conductive polysilicon.

16. The apparatus as defined by claim 9 wherein the first conductive path is substantially integrated with the substrate.

17. The apparatus as defined by claim 9 wherein the second conductive path is substantially integrated with the substrate.

18. An electronic apparatus comprising:
a substrate having a front side and a back side;
a front side contact on the front side of the substrate;
a first back side contact and a second back side contact, the first and second back side contacts being on the back side of the substrate;
first means for electrically connecting the front side contact and the first back side contact, the first electrically connecting means extending through the substrate; and
second means for electrically connecting the first back side contact with the second back side contact.

19. The electronic apparatus as defined by claim 18 wherein further comprising means for passivating the second electrically connecting means.

20. The electronic apparatus as defined by claim 18 wherein the first electrically connecting means is substantially integrated into the substrate.
